(19) United States
(12) Patent Application Publication
(10) Pub. No.: US 2025/0291170 A1
(43) Pub. Date: Sep. 18, 2025

(54) OPTICAL FILTERING DEVICE AND MEMS SHUTTER

(71) Applicant: Hitachi High-Tech Corporation, Minato-ku, Tokyo (JP)

(72) Inventors: Yasuhiro YOSHIMURA, Tokyo (JP); Hitoyuki TOMOTSUNE, Tokyo (JP); Masatoshi KANAMARU, Tokyo (JP); Takanori AONO, Tokyo (JP); Yuko OTANI, Tokyo (JP); Nobuhiko KANZAKI, Tokyo (JP)

(21) Appl. No.: 18/860,304

(22) PCT Filed: Jul. 4, 2022
(86) PCT No.: PCT/JP2022/026555

§ 371 Date: Oct. 25, 2024

(51) Int. Cl. G02B 21/32; G02B 21/00; G02B 21/10; G02B 26/02

(52) U.S. Cl. CPC G02B 21/32; G02B 21/0016; G02B 21/10; G02B 26/023

(57) ABSTRACT

To provide a highly reliable optical filtering device used as a spatial filter of a dark field microscope, which is capable of controlling a shutter at a desired opening angle without fully opening the shutter. The shutter configured to be open and closed by voltage control; and a substrate having a shutter opening portion serving as a movable region of the shutter are included. The substrate has a stopper provided on a side surface of the shutter opening portion and extending in a thickness direction of the substrate, any cross section of the stopper in the thickness direction of the substrate having substantially the same shape, the shutter has a cut-out portion, and when the shutter is open, the cut-out portion abuts against the stopper.

### TECHNICAL FIELD

The present invention relates to a structure of an optical filtering device configured with MEMS, and more particularly to an effective technique applied to a MEMS shutter mounted in a dark field microscope.

### BACKGROUND ART

A defect observation device includes a scanning electron microscope (SEM) or the like for reviewing and classifying various defects, foreign matter, and the like (hereinafter, referred to as “defects or the like”) that occur on a surface of a wafer, which is a semiconductor substrate in a semiconductor manufacturing line or the like.

Preferably, the defect observation device further includes an optical microscope. The defect observation device has a function of controlling the optical microscope, efficiently and automatically detecting defects or the like on the surface of the wafer, and performing coordinate alignment. With respect to minute defects or the like detected by the optical microscope, a shape thereof can be observed in detail and component analysis can be performed by controlling the SEM. The optical microscope is preferably capable of being used as a dark field optical microscope (DFOM).

The defect observation device has a function of automatically outputting SEM images, classification data of defects or the like, element analysis data, and the like, and can also create a defect map based on output data. The defect observation device can also observe, classify, and analyze defects or the like based on the created defect map. Therefore, the defect observation device is also called a review SEM. The defect observation device is also called as a defect review-SEM or a wafer inspection SEM.

In the defect observation device, the optical microscope and the SEM have a common stage, and the wafer placed on the stage can be observed with an optical microscope, a position of a detected defect of the Like can be specified, and a defect or the like can be observed with the SEM. For example, defects or the like can be searched in a range of several hundred nanometers using a dark field microscope of the defect observation device according to a defect map having an accuracy of several tens of microns, and a position of a defect or the like can be specified with accuracy of several microns or less.

Accordingly, it is possible to correct deviation between coordinate systems of the optical microscope and the SEM, improve a success rate of defect observation, and maintain a high throughput. In a manufacturing process of a semiconductor device, it is possible to early detect a defect or the like causing a defect such as an insulation failure or a short circuit in wiring, find out a generation source, and prevent a decrease in yield.

In the dark field microscope, a pupil filter corresponding to a type of defect or the like is required, and a minute shutter having a dimension of 1 mm or less corresponding to various types of defects or the like is required. It is considered that various spatial filters can be formed by opening and closing such a shutter.

In defect detection according to a dark field optical system in the related art that does not use such a shutter, spatial characteristics and polarization characteristics on a pupil plane of scattered light from various defects are used, a possibility of determining a defect and wafer roughness, which becomes a detection noise, is further enhanced by using a spatial filter and a polarizing filter.

Since a shape of a spatial filter that is advantageous for detection differs depending on a type of a defect or the like, in order to improve detection sensitivity of a plurality of types of defects, a shutter array in which minute shutters are arrayed is used, and a mechanism for individually switching opening and closing of a shutter and a switching circuit or the like that controls the same are necessary. By using the shutter switching mechanism, locations at which the shutter is opened and closed can be selected, and a plurality of types of spatial filters can be configured.

As a background art of the present technical field, for example, there is a technique as disclosed in PTL 1. PTL 1 discloses “an optical filtering device including: a shutter array in which shutter patterns are formed in a two-dimensionally arrayed relationship on an optically opaque thin film produced on a SOI wafer and the SOI wafer is removed at portions thereof on a lower side of the shutter patterns to form perforation portions while working electrodes are formed at a remaining portion of the SOI wafer; a glass substrate having electrode patterns formed on a surface thereof and having the shutter array mounted thereon; and a power supply section for supplying electric power to the electrode patterns formed on the glass substrate and the working electrodes of the SOI wafer, in which the electric power to be: supplied from the power supply section to the electrode patterns and the working electrodes is controlled to cause the shutter patterns formed in the two-dimensionally arrayed relationship to Carry out opening and closing movements with respect to the perforation portions, and the shutter patterns have a protrusion at an end portion thereof.”

### CITATION LIST

### Patent Literature

PTL 1: W02012/105705

### SUMMARY OF INVENTION

### Technical Problem

In general, a shutter array device (optical filtering device) configured with Micro Electro Mechanical Systems (MEMS) is generally formed using a Silicon On Insulator (SOI) substrate in which SiO₂ is inserted between a Si substrate and a surface Si layer. When the shutter is fully opened, static electricity or moisture in air can cause the open shutter to stick to a wall surface of a shutter opening portion in the Si substrate, making it impossible to control opening and closing of the shutter.

PTL 1 does not mention the problem of sticking of the shutter to the Si substrate as described above and a method for solving the problem.

When the shutter is fully opened, a stress generated in a rotatable beam supporting the shutter becomes high, and a life when the shutter is repeatedly opened and closed is shortened.

Further, in order to prevent sticking of the shutter to the wall surface of the shutter opening portion, a control method is conceivable in which the shutter is not fully opened from the beginning and is kept stationary in a space of the shutter opening portion.

However, in the shutter that is driven by an electrostatic force according to a voltage applied to the shutter and the substrate, an opening degree of the shutter differs depending on a potential difference between the shutter and an opening portion, that is, the Si substrate, and as the shutter opens and approaches the wall surface of the shutter opening portion, an electric field strength acting on the shutter and the opening portion becomes large, causing pull-in, in which the shutter opens suddenly at a certain potential difference, making it difficult to keep the shutter stationary in the space of the shutter opening portion.

Therefore, an object of the invention is to provide a highly reliable optical filtering device used as a spatial filter of a dark field microscope, which is capable of controlling a shutter at a desired opening angle without fully opening the shutter.

### Solution to Problem

In order to solve the above problems, according to the invention, a shutter configured to be open and closed by voltage control; and a substrate having a shutter opening portion serving as a movable region of the shutter are included, in which the substrate has a stopper provided on a side surface of the shutter opening portion and extending in a thickness direction of the substrate, any cross section of the stopper in the thickness direction of the substrate having substantially the same shape, the shutter has a cut- out portion, and when the shutter is open, the cut-out portion abuts against the stopper.

### Advantageous Effects of Invention

According to the invention, it is possible to implement a highly reliable optical filtering device used as a spatial filter of a dark field microscope, which is capable of controlling the shutter at a desired opening angle without fully opening the shutter.

Accordingly, since the shutter is not fully opened, it is possible to prevent sticking of the shutter to a wall surface of the shutter opening portion, and it is possible to reduce a stress generated in a beam portion supporting the shutter, thereby improving reliability of a defect inspection device, a dark field microscope, an optical inspection device, and a review SEM.

Problems, configurations, and effects other than those described above will be clarified by the following description of embodiments.

### BRIEF DESCRIPTION OF DRAWINGS

FIG. 1 is a diagram showing a schematic configuration of a defect observation device according to Embodiment 1.

FIG. 2 is a diagram showing a schematic configuration of an optical microscope serving as a defect detection unit of the defect observation device in FIG. 1.

FIG. 3A is a schematic enlarged view showing a shutter array device and a microlens array.

FIG. 3B is a schematic enlarged view showing a state in which shutters constituting the shutter array device in FIG. 3A are closed except for a part thereof.

FIG. 3C is a schematic enlarged view showing a state in which all the shutters constituting the shutter array device in FIG. 3A are closed.

FIG. 3D is a diagram showing a spatial filter corresponding to a state of the shutter array device in FIG. 3A.

FIG. 3E is a view showing a spatial filter corresponding to a state of the shutter array device in FIG. 3B.

FIG. 3F is a diagram showing a spatial filter corresponding to a state of the shutter array device in FIG. 3C.

FIG. 4 is a perspective view showing an example of a shutter array device (5×5 array).

FIG. 5A is a perspective view of one shutter array according to Embodiment 1.

FIG. 5B is a top view of the shutter array in FIG. 5A.

FIG. C is a perspective view showing a state in which a shutter of the shutter array in FIG. 5A is open.

FIG. 5D is a top view of the shutter array in FIG. 5C.

FIG. 6A is a diagram showing a voltage application state and an operation of the shutter array.

FIG. 6B is a diagram showing a modification of FIG. 6A.

FIG. 6C is a diagram showing a modification of FIG. 6A.

FIG. 7 is a top view of a shutter array according to Embodiment 2.

FIG. 8 is a top view of a shutter array according to Embodiment 3.

FIG. 9 is a top view of a shutter array according to Embodiment 4.

FIG. 10A is a cross-Sectional view showing shutter array manufacturing process according to Embodiment 5.

FIG. 10B is a cross-sectional view showing a process following FIG. 10A.

FIG. 10G is a cross-sectional view showing a process following FIG. 10B.

FIG. 10D is a cross-sectional view showing a process following FIG. 10C.

FIG. 11 is a perspective view showing a mounting structure of a shutter array device according to Embodiment 6.

FIG. 12 is a perspective view showing a mounting structure of a shutter array device according to Embodiment 7.

### DESCRIPTION OF EMBODIMENTS

Hereinafter, embodiments of the invention will be described with reference to the drawings. Detailed description of overlapping portions will be omitted.

### Embodiment 1

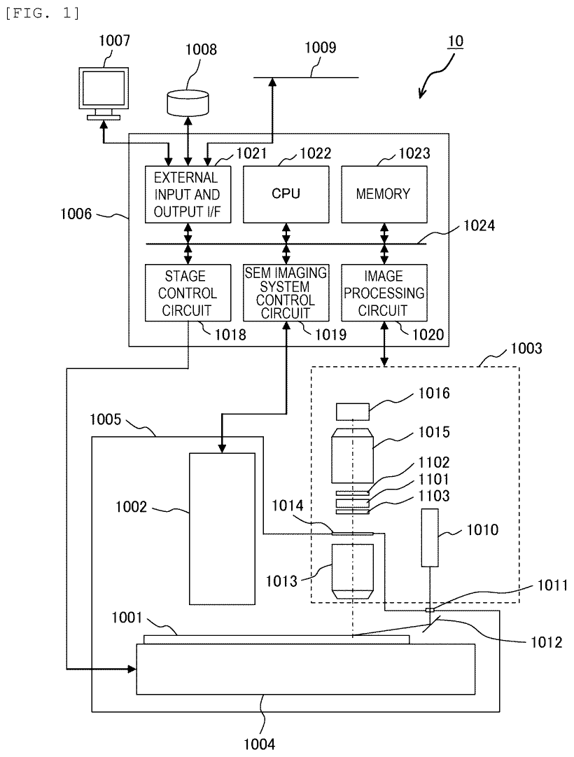

First, with reference to FIGS. 1 to 3F, a review SEM, an optical inspection device, a dark field microscope, and an optical filtering device to which the invention is applied will be described. In the present embodiment, a defect observation device for observing and inspecting a defect or the like on a wafer is described as an example of the dark field microscope.

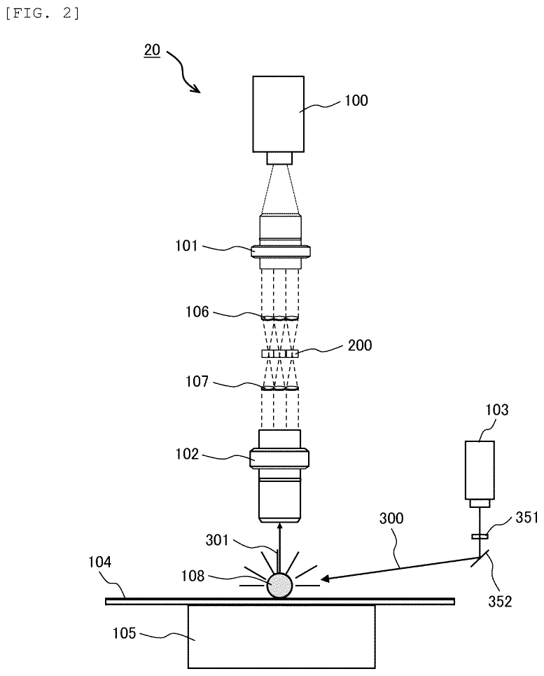

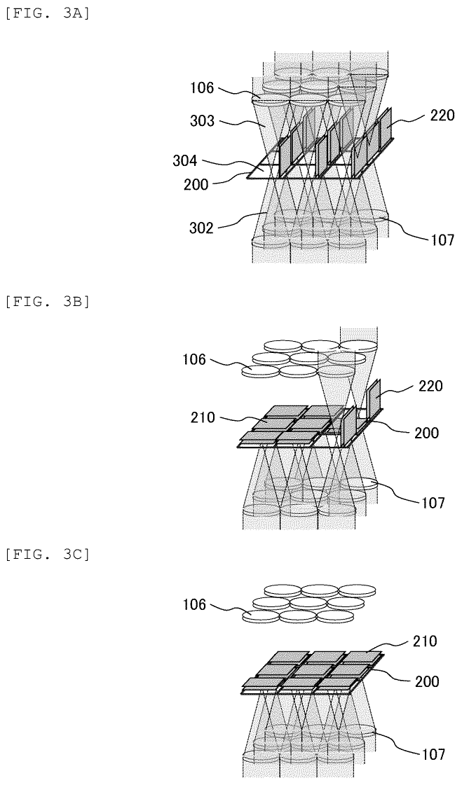

FIG. 1 is a diagram showing a schematic configuration of a defect observation device according to the present. embodiment, FIG. 2 is a diagram showing a schematic configuration of an optical microscope serving as a defect detection unit of the defect observation device in FIG. 1. FIGS. 3A to 3C are schematic enlarged views showing a shutter array device and a microlens array, and show a state in which all shutters are opened (FIG. 3A), a state in which shutters are closed except for a part thereof (FIG. 3B), and a state in which all the shutters are closed (FIG. 3C). FIGS. 3D to 3F are diagrams showing spatial filters corresponding to FIGS. 3A to 3C, respectively.

As shown in FIG. 1, a defect observation device 10 according to the present embodiment includes a scanning electron microscope (SEM) 1002, a dark field microscope 1003 as the defect detection unit, a control unit 1006, terminal 1007, a recording device 1008, and a network 1009.

The scanning electron microscope 1002 is provided in a vacuum chamber 1005 together with a stage 1004. A wafer 1001 is placed on the stage 1004. The wafer 1001 can be moved together with the stage 1004 movable along an X axis and a Y axis. Accordingly, any surface of the wafer 1001 can be observed by the scanning electron microscope 1002 and the dark field microscope 1003.

The dark field microscope 1003 includes a laser light source 1010, an objective lens 1013, an imaging lens 1015, and an imaging element 1016.

The objective lens 1013 is provided in the vacuum chamber 1005. Therefore, a vacuum sealing window 1014 is provided so that light passing through the objective lens 1013 reaches the imaging element 1016. Between the vacuum sealing window 1014 and the imaging lens 1015, a microlens array 1103, a shutter array device 1101, and a microlens array 1102 are provided in this order from a vacuum sealing window 1014 side. A light beam emitted from the laser light source 1010 passes through a vacuum sealing window 1011 and is emitted onto an upper surface of the wafer 1001 through a mirror 1012.

Light reflected by the upper surface of the wafer 1001 passes through the objective lens 1013 and the vacuum sealing window 1014 in this order, passes through the microlens array 1103, the shutter array device 1101, and the microlens array 1102 in this order, is imaged by the imaging lens 1015, and is detected by the imaging element 1016.

As the imaging element 1016, a two-dimensional CCD sensor, a line CCD sensor, a TDI sensor group in which a plurality of TDIs are provided in parallel, a photodiode array, and the like are used. Here, the COD. is an abbreviation for Charge-Coupled Device. TDI is an abbreviation for Time Delay Integration.

The scanning electron microscope 1002 and the dark field microscope 1003 are fixed so as to maintain an accurate distance.

The control unit 1006 includes a stage control circuit 1018, an SEM imaging system control circuit 1019, an image processing circuit 1020, an external input and output interface 1021, a central processing unit 1022 (CPU), and a memory 1023.

The stage control circuit 1018, the SEM imaging system control circuit 1019, and the image processing circuit 1020 are connected to the external input and output interface 1021, the central processing unit 1022, and the memory 1023 via a bus 1024.

The stage control circuit 1018, the SEM imaging system control circuit 1019, and the image processing circuit 1020 are circuits for moving the wafer 1001, observing defects on the surface of the wafer 1001, and performing other operations. The image processing circuit 1020 integrates signals of an image acquired by the imaging element 1016, performs data conversion or the like, determines a type of a defect or the like, and specifies a position and size of the defect or the like. Information related to a result of determination, specification, or the like is referred to as “defect information” in the present specification.

The defect information is input to the recording device 1008 or the memory 1023. The memory 1023 is used mainly for temporary storage. On the other hand, the recording device 1008 can be used for accumulating and storing the acquired defect information.

In the control unit 1006, based on the defect information, the stage control circuit 1018 controls the stage 1004 and the SEM imaging system control circuit 1019 controls the scanning electron microscope 1002. The control unit 1006 observes some or all of defects or the like detected by the dark field microscope 1003 in detail, classifies defects or the like, analyzes a cause of the defect, and the like. The control unit 1006 also controls focus and output of an SEM image, controls analysis, analyzes data obtained by the scanning electron microscope 1002, and corrects a position of a defect or the like obtained by the dark field microscope 1003. Further, the control unit 1006 can perform display on the terminal 1007, data transfer via the network 1009, and the like.

The terminal 1007 performs a condition setting related to observation of a defect or the like. The terminal 1007 performs parameter setting for controlling the scanning electron microscope 1002, the dark field microscope 1003, and the stage 1004. In the terminal 1007, a setting related to an opening and closing operation of a shutter (described later) of the shutter array device 1101 is also performed. Further, in the terminal 1007, a speed when the shutter opens can be adjusted. In this case, the speed at which the shutter is opened can be adjusted by adjusting a shape of a voltage curve applied to the shutter, or, in a case of a straight line, a slope, and further, it is possible to set a sequence for applying a voltage in multiple stages. An open or close state of the shutter can be confirmed on the terminal 1007 by converting an image obtained by the imaging element 1016 into a pupil image, and further, a method can be adopted in which a voltage applied to the shutter array device 1101 is adjusted while viewing the image converted into the pupil image. Accordingly, it is possible to prevent a voltage value applied to the shutter from becoming too large, and it is possible to prevent dielectric breakdown of a shutter portion and damage and failure of a shaft portion of the shutter.

In the shaft portion of the shutter that supports and rotates the shutter, a force acts as an elastic body that returns to the closed state against a stress in the open State of the shutter. An opening angle is determined based on a balance between the force and an electrostatic force generated by the voltage application to open the shutter. Therefore, by adjusting a voltage application curve, an opening speed can be adjusted. The opening angle of the shutter is determined by a value of an applied voltage.

The dark field microscope 1003, which is the defect detection unit of the defect observation device 10 in FIG. 1, will be described in detail with reference to FIG. 2. In FIG. 2, the dark field microscope is denoted by reference sign 20, and other reference signs are used which differ from those in FIG. 1, but a configuration and function of each part are similar as those in FIG. 1.

As shown in FIG. 2, the dark field microscope 20 according to the present embodiment includes an imaging element (sensor) 100, an imaging lens 101, and an objective lens 102. The microlens arrays 106 and 107 are provided between the imaging lens 101 and the objective lens 102. A shutter array device 200 (optical filtering device) is provided between the microlens arrays 106 and 107. The microlens arrays 106 and 107 and the shutter array device 200 are provided near a pupil plane of the dark field microscope 20.

The objective lens 102 is configured such that a light beam 300 emitted from a laser light source 103 to a wafer 104 is reflected by a surface of the wafer 104 and a reflected light 301 is incident on the objective lens 102. The light that passes through the objective lens 102 passes. through the pupil plane (Fourier transform plane) and the imaging lens 101, reaches the imaging element 100, and is detected as an electrical signal. The light beam 300 emitted from the laser light source 103 passes through a vacuum sealing window 351, is reflected by a mirror 352, and is emitted onto the wafer 104.

When a defect 108 exists in the wafer 104, the light beam 300 that strikes the defect 108 is reflected, and the reflected light 301 different from normal light is generated. The reflected light 301 is detected by the imaging element 100, and data corresponding to an image of the defect 108 can be acquired from the image processing circuit 1020 in FIG. 1, By moving a stage 105, the defect 108 that exists on the surface of the wafer 104 can be found.

The shutter array device and the microlens array in FIGS. 1 and 2 will be described in detail with reference to FIGS. 3A to 3F.

FIG. 3A shows a state in which all shutters 220 of the shutter array device 200 are open. In FIG. 3A, the shutter array device 200 is provided between the microlens arrays 106 and 107. All the shutters 220 of the shutter array device 200 are open. Therefore, as shown in FIG. 2, reflected light 302 passing through the shutter array device 200 from a lower side of a paper surface is converged and focused on the shutter opening portion 304, and becomes light 303.

FIG. 3B shows a state in which a part of the shutter array device 200 other than the shutter 220 is closed. FIG. 3C shows a state in which all the shutters 210 of the shutter array device 200 are closed. Thus, a plurality of shutters (closed) 210 and a plurality of shutters (open) 220 are configured to be independently openable and closable.

FIGS. 3D to 3E show spatial filters corresponding to the states shown in FIGS. 3A to 3C, respectively. FIGS, 3D to 3F are diagrams viewed from above or below the shutter array device 200.

In the drawings, a shutter closed state 211. 13. indicated by black, and a shutter open state 221 13 indicated by white. By individually controlling ON and OFF for each pixel of the shutter array device 200, a plurality of types of spatial filters (spatial masks) can be configured.

In FIGS. 3A to 3C, the shutters 210 and 220 of the shutter array device 200 and lenses of the microlens arrays 106 and 107 are provided in three rows and three columns, but the disposition is just an example and a larger matrix may be formed if necessary.

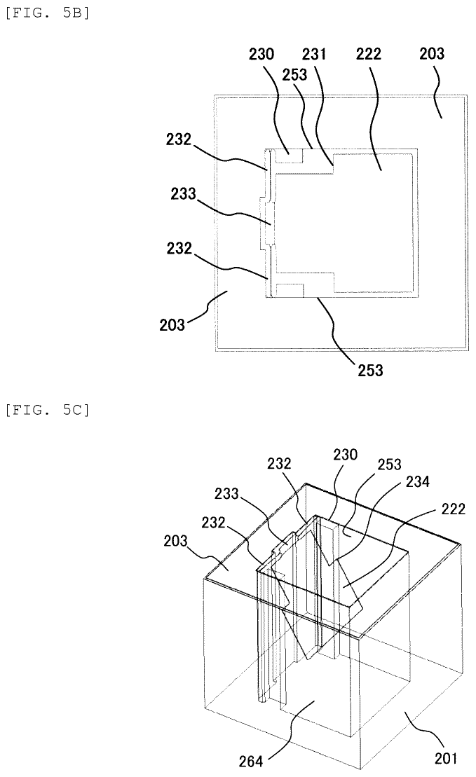

Next, a problem to be solved by the invention described above will be described in detail with reference to FIGS. 6A to 6C, FIGS, 6A to 60 are longitudinal cross-sectional views of one shutter in the shutter array device 200, each showing an operation of the shutter. FIGS. 6A to 6C show potentials (+) and potentials (−) schematically showing a voltage application state of a shutter array.

As shown in FIG. 6A, a voltage is applied to a shutter 212 via a shutter support portion 203 so that the shutter 212 has a positive potential (V1), and to a substrate 201 so that the substrate 201 has a negative potential or a potential 0 (V2). A resulting potential difference creates an electrostatic force, causing the shutter 212 to open. Even if the potentials of V1 and V2 are set inversely, an operation behavior of the shutter is the same.

As shown in the figure, a lower surface of the shutter 212 is positively charged, and an inner wall surface 282 of the substrate 201 is negatively charged. Accordingly, the shutter 212 rotates around a shaft portion (torsion beam 232) to move in the shutter opening portion 264. As a result, the shutter opens. When the application of the voltage is stopped, a restoring force of the shaft portion (torsion beam 232) causes the shutter to return to the closed state.

For example, when V1 is set to a positive potential of +10 V to +200 V and V2 is set to a negative potential of −10 V to −200 V, an applied voltage is 20 V to 400 V. When the voltage applied to the shutter is increased, an opening angle 250 of the shutter increases according to the applied voltage. The voltage applied to the shutter changes depending on a size of the shutter 212, and the invention is not limited to the above example.

On the other hand, as shown in FIG. 6B, when an opening angle 251 of the shutter 212 reaches a certain angle, a distance between the shutter 212 and the substrate 201 becomes short, So that an electrostatic force, which is inversely proportional to a square of the distance, becomes larger than a reaction force with respect to shutter rotation of the torsion beam 232 that supports the shutter 212, causing pull-in in which the shutter 212 suddenly opens fully, resulting in a state of the shutter 212 shown in FIG. 6C.

As shown in FIG. 60, when the shutter 212 is fully opened, due to the influence of static electricity or moisture in the air, the opened shutter 212 may stick to the inner wall surface 282 of the shutter opening portion 264 provided in the substrate 201, and opening and closing control over the shutter 212 may not be performed. In order to prevent such sticking of the shutter, it is preferable that the shutter 212 is not fully opened but is stationary in a space of the shutter opening portion 264. When the shutter 212 is opened midway and held stationary in air, there is a concern about the occurrence of pulling in. Therefore, the invention proposes a stopper structure as described below.

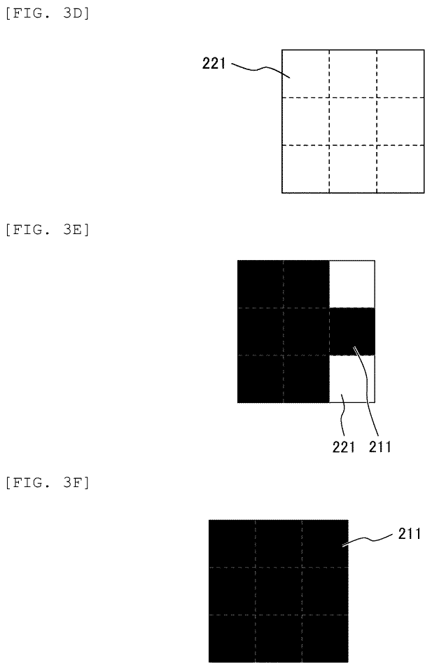

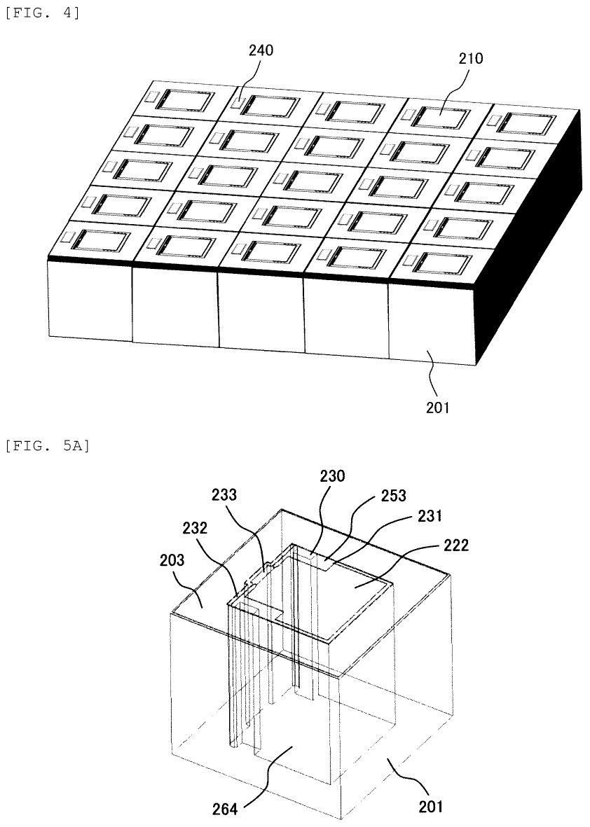

Next, the optical filtering device according to the present embodiment will be described with reference to FIGS. 4 to 5D. FIG. 4 is a perspective view showing an example of the shutter array device (5×5 array) according to the present embodiment. FIG. 5A is a perspective view showing one shutter array according to the present embodiment, and FIG. 5B is a top view thereof. FIG. 5C is a perspective view showing a state in which the shutter is open, and FIG. 5D is a top view thereof. In FIGS. 5A to 5D, an electrode is omitted.

As shown in FIG. 4, the optical filtering device according to the present embodiment is implemented by a 5×5 array with 25 shutter arrays provided 5 by 5 vertically and horizontally. Each of the shutter arrays is provided with an electrode pad 240, and controls opening and closing of the shutter 210 as described above by applying a voltage through the electrode pad 240.

Here, in the optical filtering device according to the present embodiment, as shown in FIGS. 5A and 5B, a shutter 222 is provided with a hinge 233, and the hinge 233 and the shutter support portion 203 are connected by the torsion beam 232, A stopper 230 is provided on a side wall surface 253 of the shutter opening portion 264, and the stopper 230 is a quadrangular prism with a cross section in a thickness direction of the substrate 201 having substantially the same shape, and is formed integrally with the substrate 201. Further, a cut-out portion 231 is provided in a recessed state by removing a part of the shutter 222. The shutter 222 has a polygonal shape at portions other than the hinge 233 and the torsion beam 232 due to the cut-out portion 231.

With the above configuration, as shown in FIG. 5C and FIG. 5D, when the shutter 222 is open, the cut-out portion 231 abuts against the stopper 230 at an abutment portion 234 and can be stopped in the space of the shutter opening portion 264.

Accordingly, even when a pull-in voltage is applied, the shutter 222 is stopped midway without being fully opened. Positions at which the stopper 230 and the cut-out portion 231 are provided are set such that the shutter 222 stops at the desired opening angle 251 (see FIG. 6B).

Since the stopper 230 and the abutment portion 234 of the cut-out portion 231 are in line contact with each other and a contact area is small, sticking of the shutter 222 to the stopper 230 does not occur.

As described above, the optical filtering device according to the present embodiment has the shutter 210 (222) configured to be open and closed by voltage control; and the substrate 201 having the shutter opening portion 264 serving as a movable region of the shutter 210 (222), in which the substrate 201 has the stopper 230 provided on a side surface of the shutter opening portion 264 and extending over entirety or a part of the thickness direction of the substrate 201, any cross section of the stopper in the thickness direction of the substrate 201 having substantially the same shape, the shutter 210 (222) has the cut-out portion 231, and when the shutter 210 (222) is open, the cut-out portion 231 abuts against the stopper 230.

Accordingly, it is possible to implement a highly reliable optical filtering device used as a spatial filter of a dark field microscope or an optical inspection device, which is capable of controlling the shutter at a desired opening angle without fully opening the shutter.

Since the shutter is not fully opened, it is possible to prevent sticking of the shutter to the wall surface of the shutter opening portion, and a stress generated in a beam portion supporting the shutter is reduced, improving reliability of the defect inspection device, the dark field microscope, the optical inspection device, and the review SEM.

### Embodiment 2

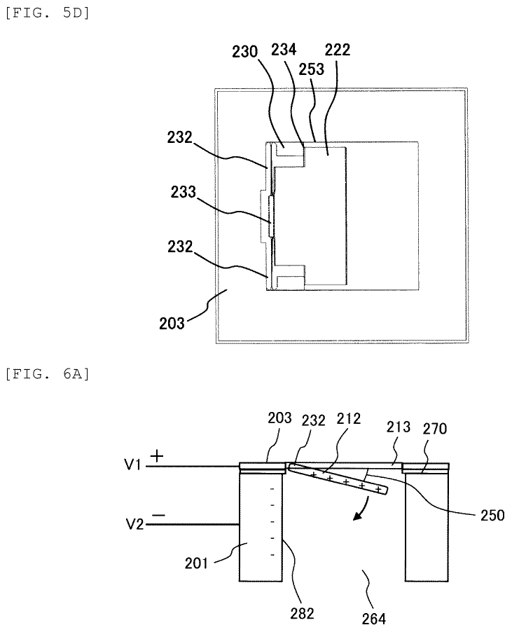

Referring to FIG. 7, an optical filtering device according to Embodiment 2 according to the invention will be described. FIG. 7 is a top view of a shutter array according to the present embodiment, showing a state where a shutter is closed. An electrode is not shown.

In the present embodiment, as shown in FIG. 7, an upper surface of a stopper 235 has a shape close to a semicircle. That is, the stopper 235 has a substantially semi-columnar shape, and a cross section in the thickness direction of the substrate 201 has substantially the same shape. The shutter 222 has a shape in which a part of the shutter 222 is cut, and a recessed cut-out portion 236 is provided with a curve. Therefore, when the shutter 222 is open and the cut-out portion 236 abuts against the stopper 235, the contact is point contact, and a contact portion is smaller than the line contact between the stopper 230 and the cut-out portion 231 of the shutter 222 shown in FIGS. 5A to 5D, making it even less likely to stick to each other.

It is preferable to provide both the stopper 235 and the cut-out portion 236, but it is sufficient to provide only one of the stopper 235 and the cut-out portion 236. A shape of a curved surface of the stopper 235 and the curve of the cut-out portion 236 is not limited to a circular arc but may be provided so that the contact portion between the stopper and the cut-out portion is small.

For example, the stopper 235 may be configured to have a curve in a part of the cross section in the thickness direction of the substrate 201, and the cut-out portion 236 may be configured to have a curve in a part thereof.

### Embodiment 3

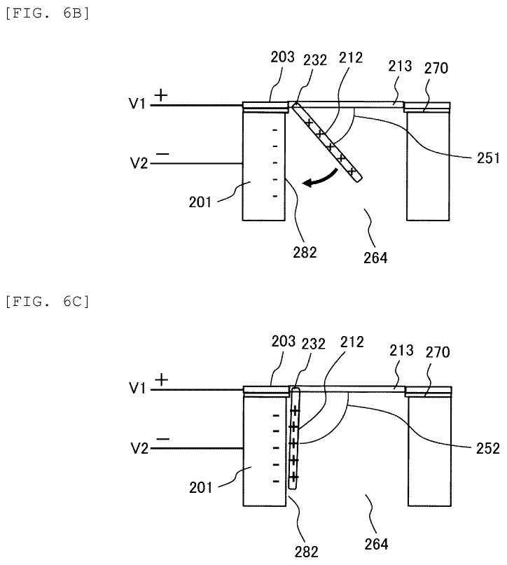

Referring to FIG. 8, an optical filtering device according to Embodiment 3 according to the invention will be described. FIG. 8 is a top view of a shutter array according to the present embodiment, showing a state where a shutter is closed. An electrode is not shown.

In the present embodiment, as shown in FIG. 8, a tapered portion 237 is provided on a surface of the stopper 230 against which the cut-out portion 231 abuts.

As in the present embodiment, by forming the stopper 230 provided with the tapered portion 237, a contact portion with the cut-out portion 231 of the shutter 222 is reduced, and sticking can be prevented.

A taper may be provided not on a stopper 230 side but on a side of the recessed cut-out portion formed by cutting out a part of the shutter 222.

### Embodiment 4

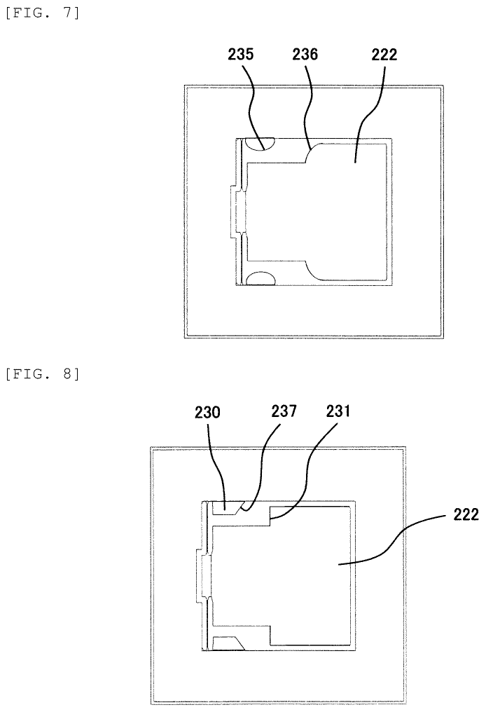

Referring to 9, an optical filtering device according to Embodiment 4 according to the invention will be described. FIG. 9 is a top view of a shutter array according to the present embodiment, showing a state where a shutter is closed. An electrode is not shown.

In the present embodiment, as shown in FIG. 9, the stopper 230 is provided at a corner of a shutter support portion 204 and is integral therewith. That is, a part of the shutter support portion 204 around the shutter 222 is removed and recessed to form a shutter opening portion 238 having a polygonal shape. The shutter 222 extends in a direction perpendicular to a movable direction, that is, on a side surface side of a shutter opening, within a range corresponding to a shutter projection portion 239. Therefore, the shutter 222 has a polygonal shape.

A difference from Embodiment 1 (FIGS. 5A to 5D) is that a width of the shutter support portion 204 is narrower when the shutter 222 protrudes in a direction of the shutter support portion 204.

As in Embodiment 2 (FIG. 7), a curved surface portion. or a curve portion may be provided in the stopper 230 and the cut-out portion 231, or a tapered portion may be provided as in Embodiment 3 (FIG. 8).

As described above, in the optical filtering device according to the present embodiment, the stopper 230 is provided at an inner corner of the shutter support portion 204, and the shutter 222 includes a wide portion connected to the cut-out portion 231 and protruding in a direction perpendicular to the thickness direction of the substrate 201.

As in the present embodiment, the stopper 230 is provided on a side wall surface of the shutter opening portion 238, and the cut-out portion 231 is provided in the shutter 222. Therefore, the shutter 222 can be stopped midway without being fully opened, thereby preventing sticking.

### Embodiment 5

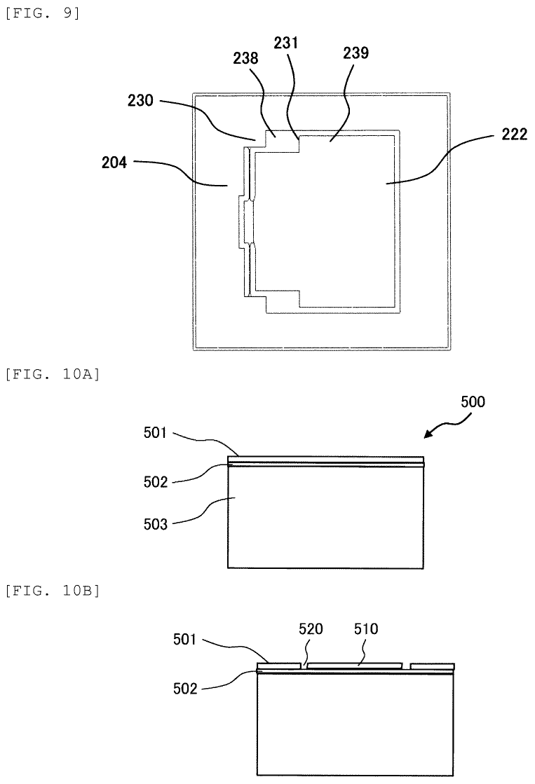

A manufacturing process of an optical filtering device according to Embodiment 5 of the invention will be described with reference to FIGS. 10A to 10D. FIGS. 10A to 10D show longitudinal cross sections at various steps in which one shutter in the optical filtering device (shutter array device) is processed,

In the present embodiment, as shown in FIG. 10A, an SOI wafer 500 is used. The SOI wafer 500 has a three-layer structure including a device layer 501, a Buried Oxide (BOX) layer 502, and a handle layer 503, thicknesses of which are approximately 0.1 μm to 10 μm, 0.1 μm to 10 μm, and 30 μm to 1000 μm, respectively.

First, a photoresist is applied to the device layer 501, and a shape of a shutter 510 (222) is patterned by a photolithography method, and then, as shown in FIG. 10B, the shape of the shutter 510 (222) is processed by etching. At this time, an opening pattern 520 is formed in the device layer 501. Thereafter, the photoresist is removed.

Next, a phot resist is applied to the handle layer 503, and a pattern of a shutter opening portion 521 is formed by a photolithography method, and then, as shown in FIG. 10C, etching is performed down to the BOX layer 502 to form the shutter opening portion 521. Thereafter, the resist is removed.

Finally, as shown in FIG. 10D, the BOX layer 502 exposed in the shutter opening portion 521 is removed by etching to expose a shutter back surface 522. In this process, the shutter 510 (222) is separated from the shutter support portion 203 except for a portion connected to the torsion beam 232 (see FIG. 5B), and a gap 523 is formed.

As in the present the shutter can be formed by processing the SOI wafer 500 from both sides.

For the etching described above, either dry etching or wet etching may be used.

FIGS. 10A to 10D show a processing step for one shutter, but in a shutter array in which a plurality of shutters are. arranged in an array, each shutter is simultaneously processed,

### Embodiment 6

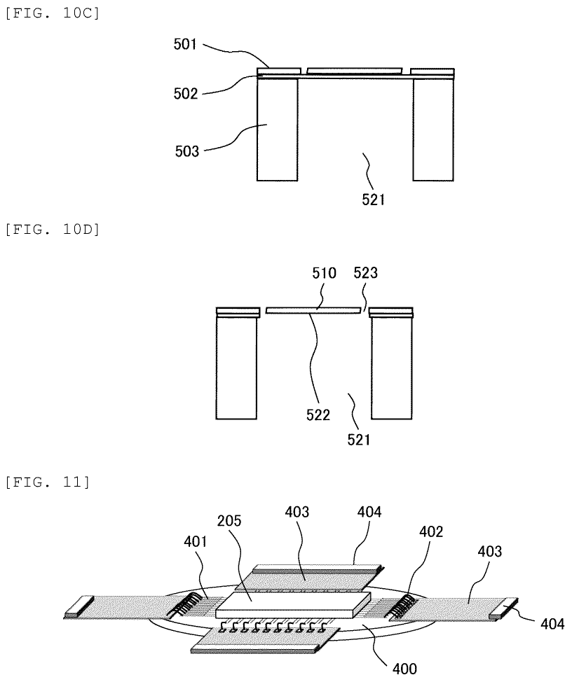

A mounting structure of a shutter array device according to Embodiment 6 in the invention will be described with reference to FIG. 11. FIG. 11 is a perspective view showing the mounting structure of the shutter array device according to the present embodiment.

The optical filtering devices described in Embodiment 1 to Embodiment 5 can be implemented in a form shown in FIG. 11, for example.

As shown in FIG. 11, the mounting structure of the shutter array device according to the present embodiment is configured to include a shutter array 205 in which shutters are arrayed, and a wiring substrate 400 in which the shutter array 205 is mounted and which includes wiring 401 for supplying a voltage for opening and closing the shutter of the shutter array 205.

The wiring 401 is connected via a bonding wire 402 to a flexible substrate 403 different from the wiring substrate 400, and is electrically connected via a connector 404 of the flexible substrate 403 to an external control device (not shown).

By adopting such h a mounting structure as in the present embodiment, it is possible to apply a voltage supplied from the external control device to the electrode pad 240 (see FIG. 4) on each shutter array and control opening and closing of the shutter 210.

The flexible substrate 403 may be a printed wiring board, and instead of the bonding wire 402, electrodes may be placed opposite each other and connected using bumps or solder, or may be connected via an anisotropic conductive film.

### Embodiment 7

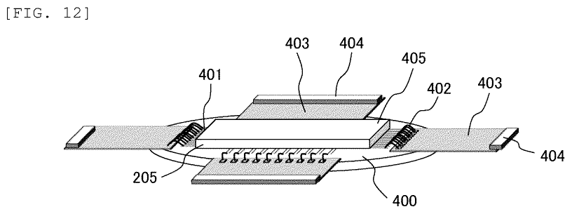

A mounting structure of a shutter array device according to Embodiment 7 in the invention will be described with reference to FIG. 12. FIG. 12 is a perspective view showing the mounting structure of the shutter array device according to the present embodiment.

In the present embodiment, the mounting structure of the shutter array device according to Embodiment 6 (FIG. 11) further includes a quartz glass (protective cover) 405 that covers the shutter array 205.

For example, by sticking and sealing the quartz glass 405 to an upper surface of the shutter array 205 by bonding with an adhesive or by other bonding methods, the shutter array 205 can be protected from dust and moisture in air.

In the optical filtering device (shutter array device) described in each of the embodiments, the shutter is operated rotating the torsion about beam with the electrostatic force, and the shutter is stopped midway by the cut-out portion of the shutter colliding with the stopper. By stopping the shutter midway, a stress generated in the torsion beam becomes smaller than when fully opened, a load applied to the torsion beam is reduced, reducing a risk of breakage and improving reliability.

On the other hand, in order to prevent the shutter from being damaged due to an impact caused by collision of the cut-out portion of the shutter with the stopper, any voltage curve such as a sine curve or a trapezoidal curve can be set when a voltage is applied, and a speed can be slowed down just before the cut-out portion of the shutter comes into contact with the stopper, thereby preventing damage to the shutter due to a collision.

The invention is not limited to the embodiments described above, and includes various modifications, For example, the embodiments described above have been described in detail to facilitate understanding of the invention, and the invention is not necessarily limited to those including all the configurations described above. A part of a configuration of a certain embodiment can be replaced with a configuration of another embodiment, and the configuration of another embodiment can be added to the configuration of a certain embodiment. A part of a configuration according to each embodiment may be added to, deleted from, or replaced with another configuration.

### REFERENCE SIGNS LIST

10 defect observation device
20, 1003 dark field microscope (defect detection unit)
100, 1016 imaging element (sensor)
101, 1015 imaging lens
102, 1013 objective lens
103, 1010 laser light source
104, 1001 water
105, 1004 stage
106, 107, 1102, 1103 microlens array
108 defect
200, 1101 shutter array device
201 substrate
203, 204 shutter support portion
205 shutter array
210, 220, 212, 222, 510 shutter
211 shutter closed state
213 gap
221 shutter open state
230, 235 stopper
231, 236 cut-out portion
232 torsion beam
233 hinge
234 abutment portion
237 tapered portion
238, 264, 521 shutter opening portion
239 shutter projection portion
240 electrode pad
250, 251, 252 opening angle
253 side wall surface
282 inner wall surface of (substrate 201)
300 light beam
301, 302 reflected light
303 Light
304 shutter opening portion
351, 1011, 1014 vacuum sealing window
352, 1012 mirror
400 wiring substrate
401 wiring
402 bonding wire
403 flexible substrate
404 connector
405 quartz glass
500 SOI wafer
501 device layer
502 BOX layer
503 handle layer
520 opening pattern
522 shutter back surface
523 gap
1002 scanning electron microscope (SEM)
1005 vacuum chamber
1006 control unit
1007 terminal
1008 recording device
1009 network
1018 stage control circuit
1019 SEM imaging system control circuit
1020 image processing circuit
1021 external input and output interface
1022 central processing unit
1023 memory
1024 bus

1. An optical filtering device comprising:
a shutter configured to be open and closed by voltage control; and
a substrate having a shutter opening portion serving as a movable region of the shutter, wherein
the substrate has a stopper provided on a side surface of the shutter opening portion and extending in a thickness direction of the substrate, any cross section of the stopper in the thickness direction of the substrate having substantially the same shape,
the shutter has a cut-out portion, and
when the shutter is open, the cut-out portion abuts against the stopper.

2. The optical filtering device according to claim 1, wherein
the stopper has a substantially semi-columnar shape.

3. The optical filtering device according to claim 1, wherein
a part of the cut-out portion has a curve.

4. The optical filtering device according to claim 1, wherein
the stopper has a curve in a part of the cross section in the thickness direction of the substrate, and
the cut-out portion has a curve in a part thereof.

5. The optical filtering device according to claim 1, wherein
the stopper has a taper at an abutment portion to be abutted against the cut-out portion,

6. The optical filtering device according to claim 1, further comprising
a torsion beam serving as an axis allowing the shutter to rotate therearound; and
a shutter support portion provided around the shutter and connected to the torsion beam to support the shutter.

7. The optical filtering device according to claim 6, wherein
the stopper is provided at an inner corner of the shutter support portion, and
the shutter includes a wide portion connected to the cut-out portion and protruding in a direction perpendicular to the thickness direction of the substrate.

9. The optical filtering device according to claim 1, further comprising:
a shutter array in which the shutters are arrayed;
a wiring substrate on which the shutter array is mounted and which has wiring for supplying a voltage for opening and closing each of the shutters of the shutter array; and
a protective cover that covers the shutter array.

9. The optical filtering device according to claim 1, wherein
the optical filtering device is mounted on any one of an optical inspection device, a dark field optical microscope, a defect inspection device, and a review SEM.

10. A MEMS shutter comprising:
a shutter configured to be open and closed by voltage control; and
a substrate having a shutter opening portion serving as a movable region of the shutter, wherein
the substrate has a stopper provided on a side surface of the shutter opening portion and extending in a thickness direction of the substrate, any cross section of the stopper in the thickness direction of the substrate having substantially the same shape,
the shutter has a cut-out portion, and
when the shutter is open, the cut-out portion abuts against the stopper.
